(19) United States
(12) Patent Application Publication
(10) Pub. No.: US 2026/0110961 A1
(43) Pub. Date: Apr. 23, 2026

(54) PHOTORESIST COMPOSITIONS AND METHODS OF MANUFACTURING SEMICONDUCTOR DEVICES USING THE SAME

(71) Applicant: Samsung Electronics Co., Ltd., Suwon-si (KR)

(72) Inventors: Kunyoung Lee, Suwon-si (KR); Juhyeon Park, Suwon-si (KR)

(21) Appl. No.: 19/317,639

(22) Filed: Sep. 3, 2025

(30) Foreign Application Priority Data
Oct. 17, 2024 (KR) 10-2024-0142355

(51) Int. Cl. G03F 7/004; G03F 7/00; G03F 7/16; H01L 21/308

(52) U.S. Cl. CPC G03F 7/0044; G03F 7/168; G03F 7/70033; H10P 50/692

(57) ABSTRACT

A photoresist composition is provided including an organometallic compound, an additive, and a solvent, and the additive may include compounds represented by Chemical Formula 1 and Chemical Formula 2:

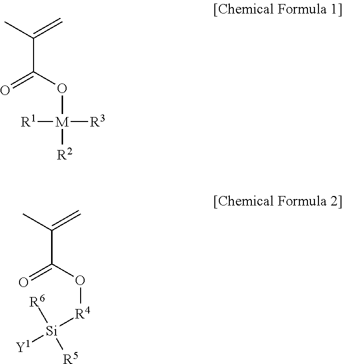

Methods of making the photoresist composition and methods of manufacturing semiconductor devices comprising the photoresist composition are also provided.

### CROSS-REFERENCE TO RELATED APPLICATION(S)

This U.S. non-provisional application claims priority under 35 USC § 119 to Korean Patent Application No. 10-2024-0142355, filed on Oct. 17, 2024, in the Korean Intellectual Property Office, the disclosure of which is herein incorporated by reference in its entirety.

### TECHNICAL FIELD

Example embodiments relate to a photoresist composition and a method of manufacturing a semiconductor device using the same.

### BACKGROUND

Advancements in electronic technology have led to rapid progress in miniaturizing semiconductor devices. Such miniaturization requires photolithography processes capable of forming micropatterns.

In a photolithography process, a photoresist may be coated on a substrate to form a photoresist layer. The photoresist layer may be exposed and developed to form a photoresist pattern. Unique physical and chemical properties of a substrate surface result in poor adhesion when the substrate comes into direct contact with the photoresist. Accordingly, an adhesive layer may be formed between the photoresist layer and the substrate to enhance the adhesion therebetween. There remains a need in the art for improved adhesion between a substrate and a photoresist layer.

### SUMMARY

Example embodiments provide a photoresist composition for reducing or preventing defects caused by residue of an adhesive layer.

Example embodiments provide a method of manufacturing a semiconductor device using a photoresist composition for simplifying a process and improving productivity.

According to an example embodiment, a photoresist composition includes an organometallic compound, an additive, and a solvent. The additive may include monomers represented by Chemical Formula 1 and Chemical Formula 2, or a copolymer represented by Chemical Formula 3.

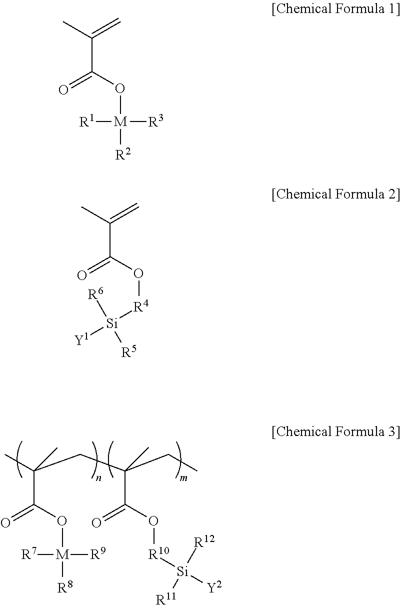

In Chemical Formula 1, organic functional groups R¹, R², and R³ are each independently a substituted or unsubstituted C1-C20 alkyl group, a substituted or unsubstituted C6-C18 cycloalkyl group, or a substituted or unsubstituted C6-C14 aryl group, and M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At).

In Chemical Formula 2, organic functional group R⁴ is a substituted or unsubstituted C1-C4 straight or branched alkyl group, organic functional groups, R⁵ and R⁶ are each independently a substituted or unsubstituted C1-C20 alkyl group, a substituted or unsubstituted C6-C18 cycloalkyl group, or a substituted or unsubstituted C6-C14 aryl group, and Y¹ is an alkoxy group, a hydroxyl group, or an amine group.

In Chemical Formula 3, organic functional groups R⁷, R⁸, R⁹, R¹¹, and R¹² are each independently a substituted or unsubstituted C1-C20 alkyl group, a substituted or unsubstituted C6-C18 cycloalkyl group, or a substituted or unsubstituted C6-C14 aryl group, R¹⁰ is a substituted or unsubstituted C1-C4 straight or branched alkyl group, Y² is an alkoxy group, a hydroxyl group, or an amine group, M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At), and n and m are each a positive integer between 1 and 100000.

According to an example embodiment, a method of manufacturing a semiconductor device includes forming a photoresist layer on a substrate, performing a heat treatment on the photoresist layer, exposing a first region of the photoresist layer, forming a photoresist pattern by removing a second region of the photoresist layer, excluding the first region, using a developer, and processing the substrate using the photoresist pattern. The photoresist layer may include an organometallic compound, an additive, and a solvent, wherein a central metal atom of the organometallic compound is tin (Sn), and the additive comprises at least one of the monomers represented by Chemical Formula 1 and Chemical Formula 2, or a copolymer represented by Chemical Formula 3 in which Chemical Formula 1 and Chemical Formula 2 are polymerized.

### BRIEF DESCRIPTION OF DRAWINGS

FIG. 1 is a flowchart illustrating a method of manufacturing a semiconductor device according to an example embodiment.

FIGS. 2A to 2C are cross-sectional views illustrating a method of manufacturing a semiconductor device according to an example embodiment and depicting a process sequence.

### DETAILED DESCRIPTION

The present disclosure may be modified in various ways, and may have various embodiments, among which specific embodiments will be described in detail with reference to the accompanying drawings. However, it should be understood that the description of the specific embodiments of the present disclosure is not intended to limit the present disclosure to a particular mode of practice, and that the present disclosure is to cover all modifications, equivalents, and substitutes included in the spirit and technical scope of the present disclosure.

In the present disclosure, the term “substituted” refers to the replacement of a hydrogen atom with deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C14 aryl group, a C1 to C20 alkoxy group, or a cyano group. The term “unsubstituted” means that a hydrogen atom remains unchanged, without replacement with any substituent.

In the present disclosure, the term “alkyl group” refers to a straight-chain or branched aliphatic hydrocarbon group, unless otherwise defined. The alkyl group may be a “saturated alkyl group” containing no double or triple bonds. The alkyl group may be a C1 to C20 alkyl group. For example, the alkyl group may be a C1 to C10 alkyl group or a C1 to C6 alkyl group. For example, a C1 to C4 alkyl group means an alkyl chain with 1 to 4 carbon atoms, and may refer to a selection from the group consisting of methyl, ethyl, propyl, isopropyl, n-butyl, isobutyl, sec-butyl, or t-butyl. For example, the alkyl group may refer to a methyl group, ethyl group, propyl group, isopropyl group, butyl group, isobutyl group, t-butyl group, pentyl group, or hexyl group.

In the present disclosure, the term “cycloalkyl group” may refer to a monovalent cyclic aliphatic hydrocarbon group, unless otherwise defined.

In the present disclosure, the term “aryl group” refers to a substituent where all atoms of a cyclic substituent possess p-orbitals, and the p-orbitals form a conjugation. The aryl group may include monocyclic or fused ring polycyclic (for example, rings sharing adjacent pairs of carbon atoms) functional groups.

An example embodiment relates to a photoresist composition and a method of forming a photolithography pattern using the photoresist composition. In an example embodiment, a method of forming a pattern using photolithography may be employed in the process of manufacturing a semiconductor device. Therefore, the following description will be provided in the context of a method of manufacturing a semiconductor device.

Hereinafter, a photoresist composition according to an example embodiment will be described in detail, followed by a description of a method of manufacturing a semiconductor device using the photoresist composition.

The photoresist composition according to an example embodiment may include an organometallic compound, an additive, and a solvent.

The organometallic compound according to an example embodiment may be an organic compound with a structure where a functional group containing carbon (C) is bonded to a central metal atom.

In an example embodiment, the organometallic compound may be a photosensitive material capable of inducing a photochemical reaction upon irradiation by a KrF excimer laser (248 nm), an ArF excimer laser (193 nm), an F2 excimer laser (157 nm), or extreme ultraviolet (EUV) light (13.5 nm).

In an example embodiment, the organometallic compound may be used as a non-chemically amplified photoresist material. For example, the organometallic compound may be a material that directly forms a photoresist pattern without a chemical amplification reaction through a catalyst (e.g., devoid of a chemical amplification reaction through catalysis) after an exposure process, e.g., in a photolithography process. For example, the organometallic compound may not exhibit chemical amplification, e.g., lack chemical amplification.

In an example embodiment, the central metal atom of the organometallic compound may be a metal with significant EUV absorption, such as polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At), but example embodiments are not limited thereto.

In an example embodiment, the central metal atom of the organometallic compound may be tetravalent tin (Sn). Tin (Sn) strongly absorbs EUV light at 13.5 nm, so that an organometallic compound containing tin (Sn) may exhibit improved sensitivity to high-energy light relative to an organometallic compound containing a central metal atom that does not strongly absorb EUV light. Accordingly, the organometallic compound according to an example embodiment may include tin as a central atom, resulting in improved photosensitivity.

In an example embodiment, the organometallic compound may include oxygen (O). An organotin compound may include, for example, at least one of an alkyltin oxo group and an alkyltin carboxyl group.

In a photoresist composition according to an example embodiment, the organometallic compound may be included in a content of 1 wt % to 30 wt %, or any range therein, for example, 1 wt % to 25 wt %, for example, 1 wt % to 20 wt %, for example, 1 wt % to 15 wt %, for example, 1 wt % to 10 wt %, for example, 1 wt % to 5 wt %, based on 100 wt % of the photoresist composition, but example embodiments are not limited thereto.

An additive according to an example embodiment may be a substance performing an auxiliary function to improve the quality and efficiency of a photoresist pattern. The additive may, for example, improve a resolution of the photoresist pattern.

In an example embodiment, the additive may include an adhesive. The adhesive may perform a function to improve the adhesion between the substrate and the photoresist composition in a photolithography process.

In an example embodiment, the additive may include monomers represented by the following Chemical Formula 1 and Chemical Formula 2.

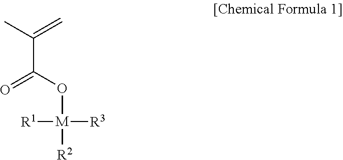

In Chemical Formula 1, R¹, R², and R³ are each independently a substituted or unsubstituted C1-C20 alkyl group, a substituted or unsubstituted C6-C18 cycloalkyl group, or a substituted or unsubstituted C6-C14 aryl group.

In addition, M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At).

In an example embodiment, M may be a metal element, substantially the same as the central metal element of the organometallic compound. Accordingly, Chemical Formula 1 may react with the organometallic compound included in the photoresist layer. For example, the bond between R¹, R², and/or R³ and M of Chemical Formula 1 may be cleaved and may bond to oxygen (O) of the organometallic compound, e.g., organotin compound. As a result, Chemical Formula 1 may be crosslinked with the organometallic compound.

In an example embodiment, M may be tin (Sn). For example, tin may be the central metal element of Chemical Formula 1. Accordingly, Chemical Formula 1 may form a Sn—O—Sn bond to the organometallic compound.

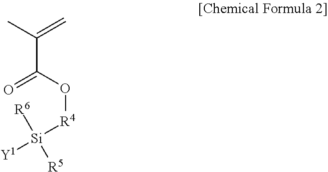

In Chemical Formula 2, R⁴ is a substituted or unsubstituted C1-C4 linear or branched alkyl group, and R⁵ and R⁶ are each independently a substituted or unsubstituted C1-C20 alkyl group, a substituted or unsubstituted C6-C18 cycloalkyl group, or a substituted or unsubstituted C6-C14 aryl group.

In addition, Y¹ is an alkoxy group, a hydroxyl group, or an amine group.

In an example embodiment, Y¹ may have a structure of either *—OH or *—NH—R, where * indicates a bonding position, and R is a linear or branched C1-C4 alkyl group. Accordingly, Chemical Formula 2 may react with silicon (Si) included in the substrate. For example, the O—H bond and/or the NH—R bond that Y¹ may have may be cleaved and may bond to Si atoms of the substrate. As a result, Chemical Formula 2 may form a Si—O—Si bond and/or a Si—NH—Si bond to the substrate.

In an example embodiment, the additive may include a copolymer represented by the following Chemical Formula 3. Chemical Formula 3 may be a copolymer of Chemical Formula 1 and Chemical Formula 2.

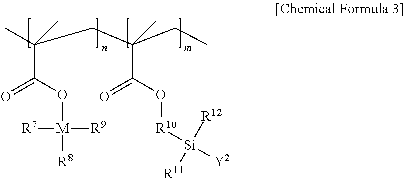

In Chemical Formula 3, R⁷, R⁸, R⁹, R¹¹, and R¹² are each independently a substituted or unsubstituted C1-C20 alkyl group, a substituted or unsubstituted C6-C18 cycloalkyl group, or a substituted or unsubstituted C6-C14 aryl group, and R¹⁰ is a substituted or unsubstituted C1-C4 linear or branched alkyl group.

In addition, Y² is an alkoxy group, a hydroxyl group, or an amine group, and n and m are each a positive integer number between 1 and 100,000.

In an example embodiment, Y² may have a structure of either *—OH or *—NH—R, where * indicates a bonding position, and R is a linear or branched C1-C4 alkyl group.

In an example embodiment, M of Chemical Formula 3 may be the same as M of Chemical Formula 1. For example, M may be a metal element, substantially the same as the central metal element of the organometallic compound. Also, Y² may have substantially the same structure as Y¹. Accordingly, a left unit of Chemical Formula 3 may be crosslinked with the organometallic compound, and a right unit of Chemical Formula 3 may form a Si—O—Si bond and/or a Si—NH—Si bond to the substrate. As a result, Chemical Formula 3 may perform all the functions of the monomers of Chemical Formula 1 and Chemical Formula 2. For example, Chemical Formula 1, Chemical Formula 2, and Chemical Formula 3 may be adhesives.

An exemplary process of polymerizing Chemical Formula 3 is as follows.

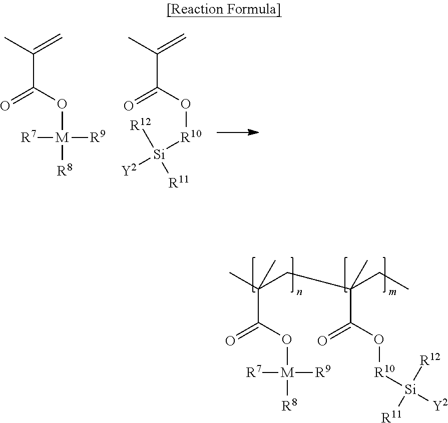

Referring to the Reaction Formula, the monomer of Chemical Formula 1 and the monomer of Chemical Formula 2 are mixed. Tetrahydrofuran (THF) may be used as a solvent. Then, a radical polymerization reaction is performed at room temperature for one day using azobisisobutyronitrile (AIBN) as an initiator. Next, a product of the radical polymerization reaction is precipitated three times using an n-hexane solution and then dried. When drying is completed, a copolymer such as Chemical Formula 3 may be prepared.

In an example embodiment, Chemical Formula 3 may be a copolymer of methyl methacrylate monomers, ethyl methacrylate monomers, or butyl methacrylate monomers, but example embodiments are not limited thereto.

In an example embodiment, the additive may include the monomers represented by Chemical Formula 1 and Chemical Formula 2 and the copolymer represented by Chemical Formula 3. For example, the additive may be a mixture in which Chemical Formula 1, Chemical Formula 2, and Chemical Formula 3 are mixed.

In an example embodiment, Chemical Formula 1 may be a compound selected from the following.

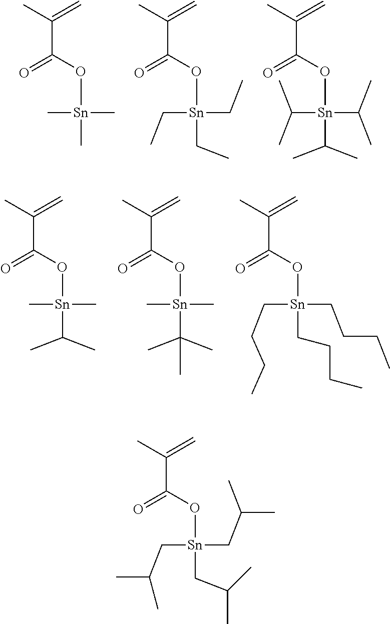

In an example embodiment. Chemical Formula 2 may be a compound selected from the following.

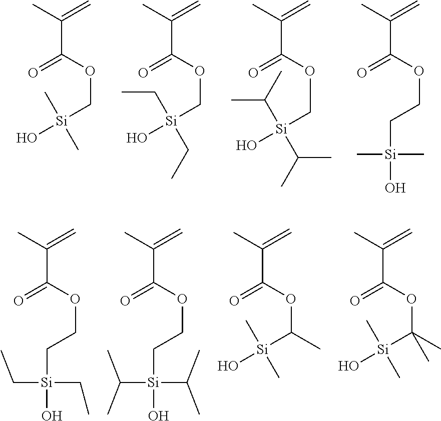

In a photoresist composition according to an example embodiment, the additive may be included in a content of about 0.001 wt % to about 5 wt %, or any range therein, for example about 0.01 wt % to about 3 wt %, based on 100 wt % of the photoresist composition, but example embodiments are not limited thereto.

In an example embodiment, the additive may further include a crosslinker, a surfactant, a hygroscopic agent, a leveling agent, an organic acid, or combinations thereof.

The crosslinker may enhance the crosslinking between the organometallic compound and the adhesive during polymerization by heat treatment. When a crosslinker is used, physical properties of a crosslinked polymer may vary depending on the presence or absence of the crosslinker, the type of crosslinker, or the content of the crosslinker. For example, an etch rate of the crosslinked polymer may vary depending on the presence or absence of the crosslinker, the type of crosslinker, or the content of the crosslinker.

The crosslinker may be at least one selected from polyfunctional (meth)acrylates, cyclic ether-containing compounds, glycol urils, diisocyanates, melamines, benzoguanamines, polynuclear phenols, polyfunctional thiol compounds, polysulfide compounds, and sulfide compounds, but example embodiments are not limited thereto.

Example polyfunctional (meth)acrylates may be compounds having two or more (meth)acryloyl groups. The polyfunctional (meth)acrylates may include, for example, polyfunctional (meth)acrylates obtained by reacting aliphatic polyhydroxy compounds with (meth)acrylic acid, caprolactone-modified polyfunctional (meth)acrylates, alkylene oxide-modified polyfunctional (meth)acrylates, polyfunctional urethane (meth)acrylates obtained by reacting (meth)acrylates having hydroxyl groups (—OH) with polyfunctional isocyanates, or polyfunctional (meth)acrylates having carboxyl groups obtained by reacting (meth)acrylates having hydroxyl groups with acid anhydrides.

When the photoresist composition according to an example embodiment contains a crosslinker, the crosslinker may be 1 part by weight to 60 parts by weight or any range therein, for example, 2 parts by weight to 50 parts by weight, or 3 parts by weight to 40 parts by weight, based on 100 parts by weight of the organometallic compound, but example embodiments are not limited thereto.

The surfactant may improve coating uniformity and wettability of the photoresist composition. In an example embodiment, the surfactant may include sulfuric acid ester salts, sulfonic acid salts, phosphoric acid esters, soaps, amine salts, quaternary ammonium salts, polyethylene glycol, alkylphenol ethylene oxide adducts, polyhydric alcohols, nitrogen-containing vinyl polymers, or combinations thereof, but example embodiments are not limited thereto.

The surfactant may be, for example, at least one selected from fluoroalkylbenzene sulfonates, fluoroalkyl carboxylates, fluoroalkyl polyoxyethylene ethers, fluoroalkyl ammonium iodides, fluoroalkyl betaines, fluoroalkyl sulfonates, diglycerin tetrakis(fluoroalkyl polyoxyethylene ethers), fluoroalkyl trimethyl ammonium salts, fluoroalkyl amino sulfonates, polyoxyethylene nonylphenyl ether, polyoxyethylene octylphenyl ether, polyoxyethylene alkyl ethers, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid esters, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonates, and alkyldiphenylether disulfonates, but example embodiments are not limited thereto.

When the photoresist composition according to an example embodiment contains a surfactant, the surfactant may be 0.001 parts by weight to 1 part by weight or any range therein, for example, 0.001 parts by weight to 0.1 parts by weight, or 0.01 parts by weight to 0.1 parts by weight, based on 100 parts by weight of the organometallic compound, but example embodiments are not limited thereto.

The dispersant may serve to uniformly disperse each constituent component of the photoresist composition within the photoresist composition. In an example embodiment, the dispersant may include epoxy resin, polyvinyl alcohol, polyvinyl butyral, polyvinylpyrrolidone, glucose, sodium dodecyl sulfate, sodium citrate, oleic acid, linoleic acid, or combinations thereof, but example embodiments are not limited thereto.

When the photoresist composition according to an example embodiment includes a dispersant, the dispersant may be included in an amount of about 0.001 wt % to about 5 wt %, or any range therein, based on 100 wt % of the photoresist composition.

A hygroscopic agent may serve to prevent adverse effects caused by moisture in the photoresist composition. For example, the hygroscopic agent may serve to prevent a metal included in the photoresist composition from being oxidized by moisture. In an example embodiment, the hygroscopic agent may include polyoxyethylene nonylphenyl ether, polyethylene glycol, polypropylene glycol, polyacrylamide, or combinations thereof, but example embodiments are not limited thereto.

When the photoresist composition according to an example embodiment includes a hygroscopic agent, the hygroscopic agent may be included in an amount of about 0.001 wt % to about 10 wt %, or any range therein, based on 100 wt % of the photoresist composition.

The leveling agent is a substance used to improve the levelness of coating during printing. Any known leveling agent, available through commercial methods, may be used as the leveling agent.

The organic acid may be p-toluenesulfonic acid, benzenesulfonic acid, p-dodecylbenzenesulfonic acid, 1,4-naphthalenedisulfonic acid, methanesulfonic acid, fluorinated sulfonium salt, malonic acid, citric acid, propionic acid, methacrylic acid, oxalic acid, lactic acid, glycolic acid, succinic acid, or combinations thereof, but example embodiments are not limited thereto.

The solvent included in the photoresist composition according to an example embodiment may include an organic solvent. The organic solvent may include at least one of an ether, an alcohol, a glycol ether, an aromatic hydrocarbon compound, a ketone, and an ester, but example embodiment are not limited thereto.

For example, the organic solvent may be ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propionate, ethoxyethoxy propionate, or combinations thereof. The solvent may be used either alone or in combination of at least two different types.

In the photoresist composition according to an example embodiment, when the solvent consists of only an organic solvent, the photoresist composition may further include water. A content of the water in the photoresist composition may be about 0.001 wt % to about 0.1 wt %, or any range therein, based on 100 wt % of the photoresist composition.

In the photoresist composition according to an example embodiment, the content of the solvent may be the remaining amount excluding the content of main constituent components such as the organometallic compound and the additive.

According to an example embodiment, the photoresist composition may contain arbitrary components within a range that does not impair the effects of the present disclosure. When the photoresist composition includes components such as the arbitrary component (for example, resin, basic quencher, or additive), the content of the solvent may be the remaining amount excluding the content of main constituent components and the arbitrary component. For example, the solvent may be included in a content of about 0.1 wt % to about 99 wt %, or any range therein, based on 100 wt % of the photoresist composition.

In an example embodiment, the photoresist composition may further include a basic quencher.

The basic quencher may control the balance of acid and basic substances in the photoresist composition. For example, the basic quencher may suppress the diffusion of acid and unnecessary chemical reactions between metal elements and organic compounds within the photoresist composition. Thus, the structural stability of the organometallic compound in the photoresist composition may be maintained, and chemical damage be prevented from occurring during the development process.

In an example embodiment, the basic quencher may include a primary aliphatic amine, a secondary aliphatic amine, a tertiary aliphatic amine, an aromatic amine, a heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. The basic quencher may include, for example, triethanolamine, triethylamine, tributylamine, tripropylamine, hexamethyl disilazane, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or combinations thereof, but example embodiments are not limited thereto.

In the photoresist composition according to an example embodiment, the basic quencher may be included in an amount of about 0.01 wt % to about 5.0 wt %, or any range therein, based on 100 wt % of the photoresist composition, but example embodiments are not limited thereto.

The above-described photoresist composition may be used to manufacture a semiconductor device, for example, an integrated circuit device. Hereinafter, a method of manufacturing a semiconductor device using the photoresist composition will be described.

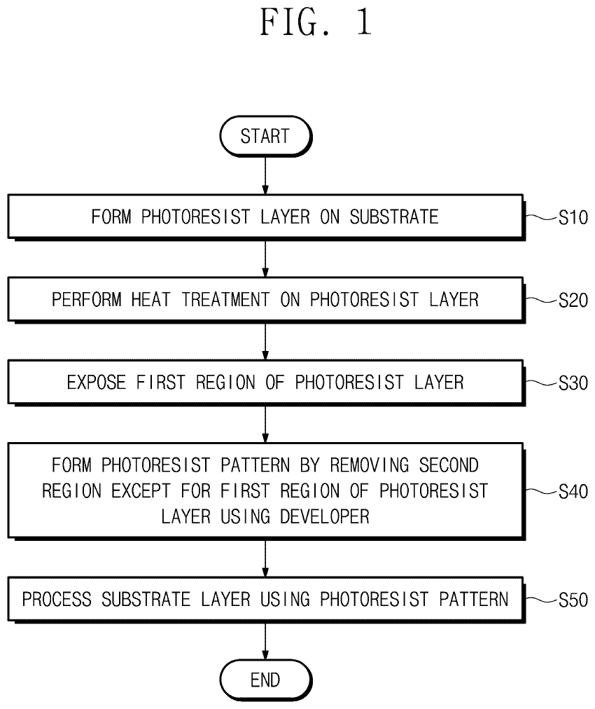

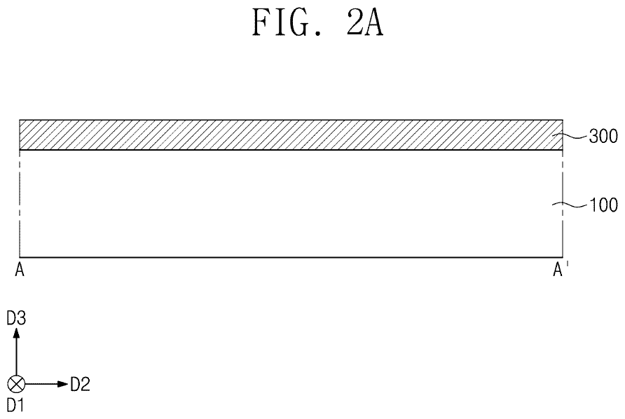

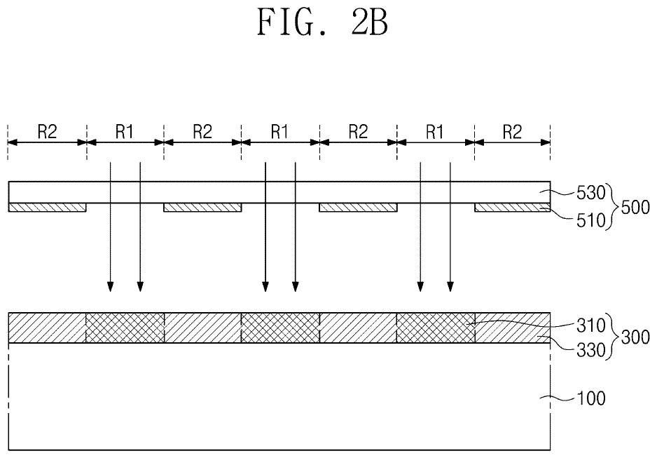

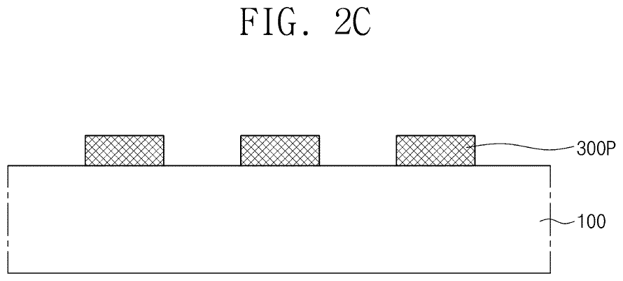

FIG. 1 is a flowchart illustrating a method of manufacturing a semiconductor device according to an example embodiment. FIGS. 2A to 2C are cross-sectional views illustrating a method of manufacturing a semiconductor device according to an example embodiment and depicting a process sequence.

Referring to FIG. 1, the method of manufacturing a semiconductor device according to an example embodiment may include forming a photoresist layer on a substrate (S10), performing a heat treatment on the photoresist layer (S20), exposing a first region of the photoresist layer (S30), forming a photoresist pattern by removing a second region of the photoresist layer, except for the first region, using a developer (S40), and processing the substrate using the photoresist pattern (S50). This will be described below in detail with reference to accompanying drawings.

Referring to FIGS. 1 and 2A, a photoresist layer 300 may be formed on a substrate 100.

The substrate 100 may be an etching target of a photoresist pattern. For example, the substrate 100 may be a material processed in an etching process to obtain a desired pattern shape through a photolithography process. The substrate 100 may include an elemental semiconductor material such as silicon (Si) or germanium (Ge), or a compound semiconductor material such as SiGe, SiC, GaAs, InAs, or InP. However, the substrate 100 is not limited thereto, and may be formed of various materials such as metal, glass, or polymer resin.

In an example embodiment, a thin film may be formed on the substrate 100. The etching target may be the thin film rather than the substrate 100. The thin film may be an insulating layer, a conductive layer, or a semiconductor layer. The thin film may be formed of, for example, metal, alloy, metal carbide, metal nitride, metal oxynitride, metal oxycarbide, semiconductor, polysilicon, oxide, nitride, oxynitride, or combinations thereof, but example embodiments are not limited thereto. In an example embodiment, a coating process of the thin film may be omitted.

In an example embodiment, a bottom anti-reflective coating (BARC) layer may be selectively formed on the substrate 100. The BARC layer may control the scattering of light from a light source used during the exposure process for manufacturing a semiconductor device or absorb light reflected from the substrate 100. The BARC layer may be formed of an organic anti-reflective coating (ARC) material for a KrF excimer laser, an ArF excimer laser, or any other light source. In an example embodiment, the BARC layer may include an organic component having a light-absorbing structure. The light-absorbing structure may be, for example, a hydrocarbon compound having one or more benzene rings or a structure in which benzene rings are fused. In an example embodiment, the BARC layer may be formed to a thickness of about 5 nm to about 100 nm, but example embodiments are not limited thereto. In an example embodiment, the formation of the BARC layer may be omitted.

In an example embodiment, a drying process and a heat treatment process may be performed to form an underlying layer below the photoresist layer 300. The heat treatment may be performed at a temperature of about 100° C. to about 300° C., or any range therein. The underlying layer may be formed between the substrate 100 and the photoresist layer 300 to prevent reflected light, reflected from the interface between the substrate 100 and the photoresist layer 300 or an interlayer hardmask during the exposure process, from being scattered into unintended photoresist regions. Accordingly, the underlying layer may prevent non-uniformity of photoresist linewidth and inhibition of pattern formation.

Then, a photoresist layer 300 may be formed on the substrate 100. The photoresist layer 300 may be formed by coating the above-described photoresist composition on the substrate 100. The photoresist layer 300 may be in a cured form through a heat treatment process after coating the photoresist composition.

For example, the forming of the photoresist layer on substrate (S20) may include a process of applying the photoresist composition to the substrate 100 by spin coating, spray coating, dip coating, aerosol coating, ink-jet printing, or the like, and may include a process of drying the applied photoresist composition to form the photoresist layer 300.

Then, a first heat treatment (bake) process may be performed. The first heat treatment process may be an operation of performing a heat treatment on the photoresist layer (S20). For example, the first heat treatment process may be a process of heating the substrate 100 on which the photoresist layer 300 is formed. Among the additives present in the photoresist layer 300, the monomer of Chemical Formula 2 and/or the copolymer of Chemical Formula 3 may react with a silicon (Si) portion of the substrate 100. Accordingly, the substrate 100 and the additive may adhere to each other. For example, the additive may perform a function of an adhesive. The first heat treatment process may be performed, for example, at a temperature of about 80° C. to about 180° C. for about 30 seconds to about 10 minutes, or any time and temperature range therein.

Referring to FIGS. 1 and 2B, an exposure process may be performed on the photoresist layer 300. For example, an operation of exposing the first region of the photoresist layer (S30) may include aligning a photomask 500 on the photoresist layer 300 and irradiating light onto the photoresist layer 300 through the photomask 500.

The light may be in an ultraviolet wavelength range. The light in the ultraviolet wavelength range may be, for example, one light selected from a KrF excimer laser (248 nm), an ArF excimer laser (193 nm), or an F2 excimer laser (157 nm). In an example embodiment, the light may be light in the extreme ultraviolet EUV wavelength range (13.5 nm).

The photomask 500 may include a transparent substrate 530 and a plurality of light-shielding patterns 510 formed in a plurality of light-shielding regions on the transparent substrate 530. The transparent substrate 530 may be formed of quartz. The plurality of light-shielding patterns 510 may be formed of chromium (Cr), but example embodiments are not limited thereto. A plurality of light-transmitting regions R1 and light-shielding regions R2 may be defined by the plurality of light-shielding patterns. The light-transmitting region R1 is a region in which the light-shielding pattern 510 is not formed, while the light-shielding region R2 is a region in which the light-shielding pattern 510 is formed.

The photoresist layer 300 may include a first region 310 and a second region 330. A region exposed to light within the second resist layer 300 is the first region 310, while a region not exposed to light, for example, a region excluding the first region 310, is the second region 330. As the exposure process is performed, the bond between the central metal atom of the organometallic compound present in the first region 310 and the organic functional group of Chemical Formula 1 or Chemical Formula 3 may be cleaved. In addition, a portion of the bonds between the central metal atom of the monomer of Chemical Formula 1 and/or the copolymer of Chemical Formula 3 and the organic functional group, among the additives present in the first region 310, may be cleaved. For example, the bond between the central metal atom M of Chemical Formula 1 and the organic functional groups R1, R2, and/or R3, or the bond between the central metal atom M of Chemical Formula 3 and the organic functional groups R7, R8, and/or R9 may be cleaved.

Then, a second heat treatment process may be performed. The second heat treatment process may be performed at a temperature of about 120° C. to about 200° C. for about 30 seconds to about 5 minutes, or any time and temperature range therein. The second heat treatment process may be performed to cause (e.g., initiate) a crosslinking reaction between the organometallic compounds. In addition, the crosslinking reaction may occur between the organometallic compound and the monomer of Chemical Formula 1 and/or the copolymer of Chemical Formula 3, among the additives. For example, a covalent bond may be formed between the organometallic compound and the central metal atom M of Chemical Formula 1 and/or Chemical Formula 3. Accordingly, the first region 310 may be polymerized by the crosslinking reaction. As a result, the first region 310 may exhibit improved adhesion to the substrate 100, making it less likely to dissolve in the developer, whereas the second region 330 may have high solubility in the developer because the composition of the photoresist layer 300 remains unchanged.

In an example embodiment, the additive present in the photoresist layer 300 may perform the function of an adhesive, eliminating the need for an additional adhesive layer to facilitate crosslinking between the substrate 100 and the photoresist layer 300.

Referring to FIGS. 1 and 2C, the photomask 500 may be removed after the exposure process is performed, and a development process may be performed. For example, an operation of removing the second region, excluding the first region, of the photoresist layer using a developer to form a photoresist pattern (S40) may be performed.

In an example embodiment, the developer may be an organic solvent. The developer may include, for example, ketones such as methyl ethyl ketone, acetone, cyclohexanone, or 2-heptanone, alcohols such as 4-methyl-2-propanol, 1-butanol, isopropanol, 1-propanol, or methanol, esters such as propylene glycol monomethyl ether acetate, ethyl acetate, ethyl lactate, n-butyl acetate, or butyrolactone, aromatic compounds such as benzene, xylene, or toluene, or combinations thereof.

When the developer is provided to the photoresist layer 300, the second region 330 may be selectively removed. For example, the developer may dissolve the photoresist layer 300 corresponding to the second region 330 to form a photoresist pattern 300P.

In an example embodiment, the photoresist pattern 300P may be a negative pattern, but example embodiments are not limited thereto. The photoresist pattern 300P may be, for example, a positive pattern formed by selectively dissolving the first region 310. In the event of a positive pattern, the developer may include a quaternary ammonium hydroxide composition, for example, tetraethylammonium hydroxide, tetrapropylammonium hydroxide, tetrabutylammonium hydroxide, or combinations thereof.

In an example embodiment, when an underlying layer is formed between the photoresist layer 300 and the substrate 100, an etching process may be additionally performed after the formation of the photoresist pattern 300P to selectively etch the underlying layer. For example, the underlying layer may be selectively etched in a region, which is not covered with the photoresist pattern 300P, using the photoresist pattern 300P as an etching mask. Accordingly, a lower pattern may be formed. The lower pattern may have a width corresponding to the photoresist pattern 300P.

Then, an etching process may be performed to etch an etching target. The etching process may be performed using the photoresist pattern 300P as an etching mask. For example, the substrate 100 may be etched using the photoresist pattern 300P as an etching mask through a dry or wet etching process.

A semiconductor device may be finally manufactured using the manufacturing method including the above-described operations.

A photoresist pattern 300P, necessary to perform a photolithography process, may be formed through the method of manufacturing a semiconductor device according to an example embodiment. The photoresist composition constituting the photoresist pattern 300P may include an organometallic compound, an additive, and a solvent. The additive may include the monomers represented by Chemical Formula 1 and Chemical Formula 2 and/or the copolymer represented by Chemical Formula 3, which serve as an adhesive for bonding the substrate 100 and the photoresist layer 300. Accordingly, the adhesion between the photoresist layer 300 and the substrate 100 may be improved, and an adhesive layer that may be additionally formed between the substrate 100 and the photoresist layer 300 may be omitted. As a result, defects in the photoresist pattern 300P that may occur during a process of forming the adhesive layer, as well as defects that may occur during a process of etching the adhesive layer, may be prevented. In addition, the photolithography process may be simplified.

As set forth above, according to example embodiments, a photoresist composition having improved adhesion may be provided.

In addition, according to example embodiments, a method of manufacturing a semiconductor device using a photoresist composition, which simplifies the process and improves productivity, may be provided.

While example embodiments have been shown and described above, it will be apparent to those skilled in the art that modifications and variations could be made without departing from the scope of the present inventive concept as defined by the appended claims.

What is claimed is:

1. A photoresist composition comprising:
an organometallic compound, an additive, and a solvent,
wherein
the additive comprises:
monomers represented by Chemical Formula 1 and Chemical Formula 2; or
a copolymer represented by Chemical Formula 3. 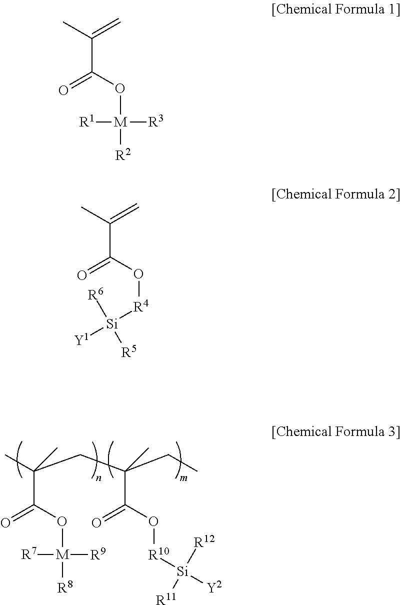
wherein,
R¹, R², and R³ are each independently a substituted or unsubstituted C1-C20 alkyl group, a substituted or unsubstituted C6-C18 cycloalkyl group, or a substituted or unsubstituted C6-C14 aryl group,
M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At),
R⁴ is a substituted or unsubstituted C1-C4 straight or branched alkyl group,
R⁵ and R⁶ are each independently a substituted or unsubstituted C1-C20 alkyl group, a substituted or unsubstituted C6-C18 cycloalkyl group, or a substituted or unsubstituted C6-C14 aryl group,
Y¹ is an alkoxy group, a hydroxyl group, or an amine group,
R⁷, R⁸, R⁹, R¹¹, and R¹² are each independently a substituted or unsubstituted C1-C20 alkyl group, a substituted or unsubstituted C6-C18 cycloalkyl group, or a substituted or unsubstituted C6-C14 aryl group,
R¹⁰ is a substituted or unsubstituted C1-C4 straight or branched alkyl group,
Y² is an alkoxy group, a hydroxyl group, or an amine group, and
n and m are each a positive integer between 1 and 100000.

2. The photoresist composition of claim 1, wherein
Y¹ has a structure selected from a group consisting of *—OH and *—NH—R,
where * represents a bonding position, and R is a C1-C4 straight or branched alkyl group.

3. The photoresist composition of claim 1, wherein
Y² has a structure selected from a group consisting of *—OH and *—NH—R,
where * represents a bonding position, and R is a C1-C4 straight or branched alkyl group.

4. The photoresist composition of claim 1, wherein
Chemical Formula 3 is a copolymer comprising methyl methacrylate, ethyl methacrylate, or butyl methacrylate monomers.

5. The photoresist composition of claim 1, wherein
the monomer represented by Chemical Formula 1 is a single compound, among compounds selected from:

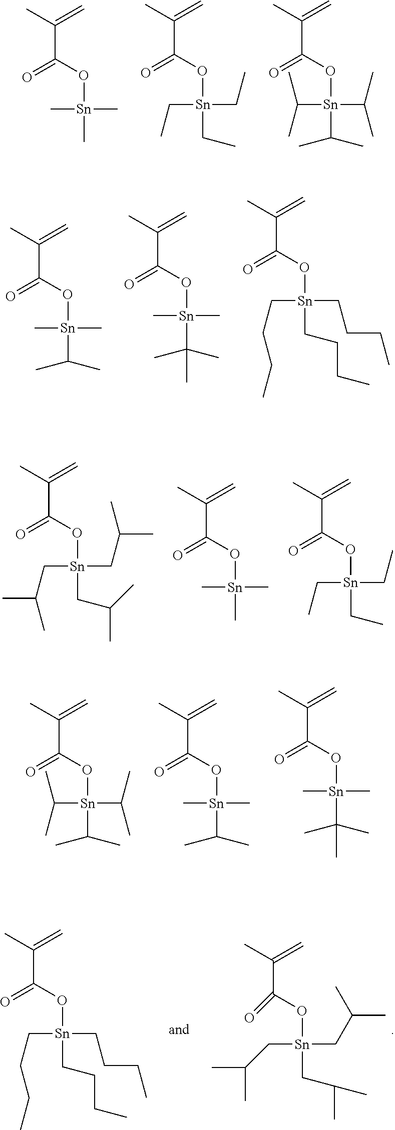

6. The photoresist composition of claim 1, wherein
the monomer represented by Chemical Formula 2 is a single compoundselected from:

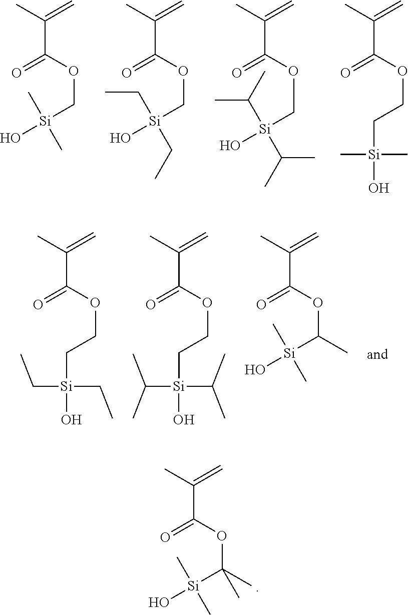

7. The photoresist composition of claim 1, wherein M is tin (Sn).

8. The photoresist composition of claim 1, wherein
a central metal atom of the organometallic compound is tin (Sn).

9. The photoresist composition of claim 1, wherein
the additive further comprises at least one selected from a group consisting of a crosslinker, a surfactant, a dispersant, a hygroscopic agent, or combinations thereof.

10. The photoresist composition of claim 1, wherein
the solvent comprises at least one selected from a group consisting of ether, alcohol, glycol ether, aromatic hydrocarbon compound, ketone, or ester.

11. A photoresist composition comprising:
an organometallic compound, an additive, and a solvent,
wherein
the additive comprises:
monomers represented by Chemical Formula 1 and Chemical Formula 2; and
a repeating unit represented by Chemical Formula 3, and
Chemical Formula 3 is a copolymer of Chemical Formula 1 and Chemical Formula 2, 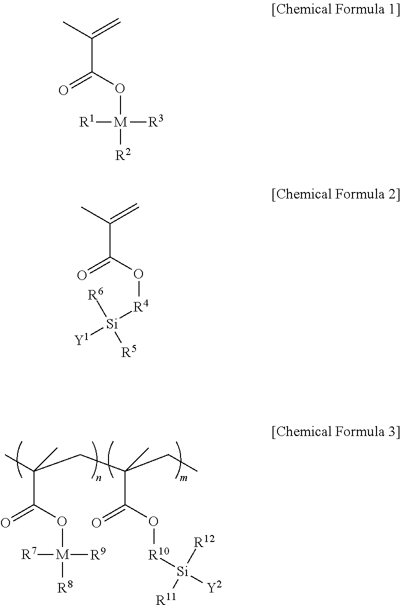
wherein
R¹, R², and R³ are each independently a substituted or unsubstituted C1-C20 alkyl group, a substituted or unsubstituted C6-C18 cycloalkyl group, or a substituted or unsubstituted C6-C14 aryl group,
M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At),
R⁴ is a substituted or unsubstituted C1-C4 straight or branched alkyl group, R⁵ and R⁶ are each independently a substituted or unsubstituted C1-C20 alkyl group, a substituted or unsubstituted C6-C18 cycloalkyl group, or a substituted or unsubstituted C6-C14 aryl group,
Y¹ is an alkoxy group, a hydroxyl group, or an amine group,
R⁷, R⁸, R⁹, R¹¹, and R¹² are each independently a substituted or unsubstituted C1-C20 alkyl group, a substituted or unsubstituted C6-C18 cycloalkyl group, or a substituted or unsubstituted C6-C14 aryl group,
R¹⁰ is a substituted or unsubstituted C1-C4 straight or branched alkyl group,
Y² is an alkoxy group, a hydroxyl group, or an amine group, and
n and m are each a positive integer between 1 and 100000.

12. The photoresist composition of claim 11, wherein
M is the same as the central metal atom of the organometallic compound, and
Y¹ and Y² each independently have a structure selected from a group consisting of *—OH and *—NH—R,
where * represents a bonding position and R is a C1-C4 straight or branched alkyl group.

13. A method of manufacturing a semiconductor device, the method comprising:
forming a photoresist layer on a substrate;
performing a heat treatment on the photoresist layer;
exposing a first region of the photoresist layer;
forming a photoresist pattern by removing a second region of the photoresist layer, excluding the first region, using a developer; and
processing the substrate using the photoresist pattern,
wherein
the photoresist layer comprises an organometallic compound, an additive, and a solvent,
a central metal atom of the organometallic compound is tin (Sn), and
the additive comprises at least one of monomers represented by Chemical Formula 1 and Chemical Formula 2, or a copolymer represented by Chemical Formula 3 in which Chemical Formula 1 and Chemical Formula 2 are polymerized, 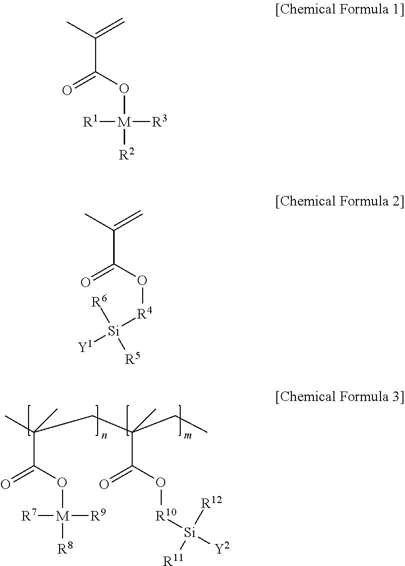
wherein
R¹, R², and R³ are each independently a substituted or unsubstituted C1-C20 alkyl group, a substituted or unsubstituted C6-C18 cycloalkyl group, or a substituted or unsubstituted C6-C14 aryl group,
M is polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), or astatine (At),
R⁴ is a substituted or unsubstituted C1-C4 straight or branched alkyl group,
R⁵ and R⁶ are each independently a substituted or unsubstituted C1-C20 alkyl group, a substituted or unsubstituted C6-C18 cycloalkyl group, or a substituted or unsubstituted C6-C14 aryl group,
Y¹ is an alkoxy group, a hydroxyl group, or an amine group,
R⁷, R⁸, R⁹, R¹¹, and R¹² are each independently a substituted or unsubstituted C1-C20 alkyl group, a substituted or unsubstituted C6-C18 cycloalkyl group, or a substituted or unsubstituted C6-C14 aryl group,
R¹⁰ is a substituted or unsubstituted C1-C4 straight or branched alkyl group,
Y² is an alkoxy group, a hydroxyl group, or an amine group, and
n and m are each a positive integer between 1 and 100000.

14. The method of claim 13, wherein
Y¹ and Y² each independently have a structure selected from *—OH and *—NH—R, and
the performing of the heat treatment on the photoresist layer comprises reacting Y¹ and/or Y² with the substrate,
where * represents a bonding position and R is a C1-C4 straight or branched alkyl group.

15. The method of claim 13, wherein
the exposing of the first region of the photoresist layer comprises crosslinking at least one of the monomer represented by Chemical Formula 1 or the copolymer represented by Chemical Formula 3 with the organometallic compound.

16. The method of claim 13, wherein
M is tin (Sn).

17. The method of claim 13, wherein
the monomer represented by Chemical Formula I is a single compound, selected from:

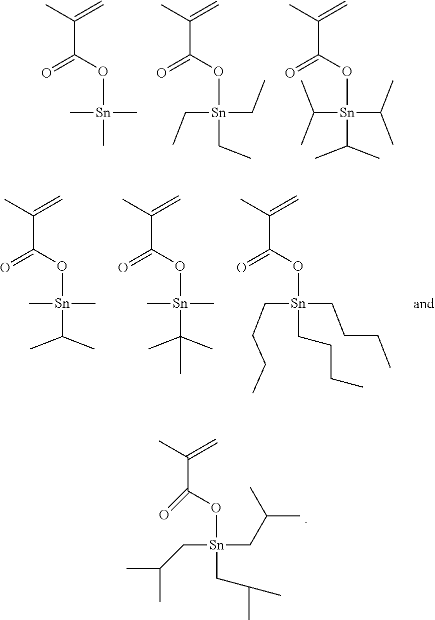

18. The method of claim 13, wherein
the monomer represented by Chemical Formula 2 is a single compoundselected from:

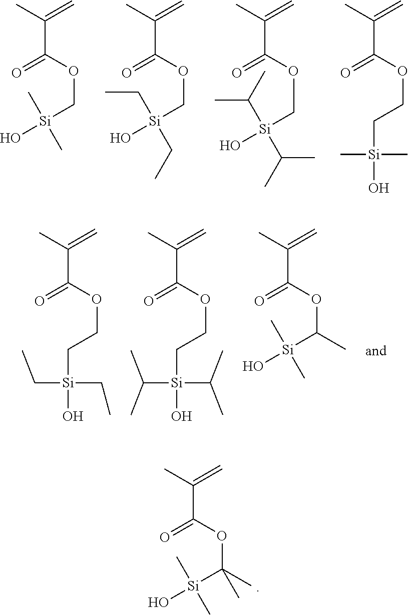

19. The method of claim 13, wherein
the exposing of the first region of the photoresist layer comprises irradiating ultraviolet (EUV) light.

20. The method of claim 13, wherein
the photoresist layer is non-chemically amplified.
